(19) United States
(12) Patent Application Publication
(10) Pub. No.: US 2007/0298623 A1
(43) Pub. Date: Dec. 27, 2007

(54) METHOD FOR STRAINING A SEMICONDUCTOR DEVICE

(76) Inventors: Gregory S. Spencer, Pflugerville, TX (US); Stanley M. Filipiak, Pflugerville, TX (US); Narayannan C. Ramani, Austin, TX (US); Michael D. Turner, San Antonio, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/426,463

(22) Filed: Jun. 26, 2006

(51) Int. Cl. H01L 21/31; H01L 21/469

(52) U.S. Cl. 438/791; 257/E21.293

(57) ABSTRACT

A strained semiconductor layer is achieved by an overlying stressed dielectric layer. The stress in the dielectric layer is increased by a radiation anneal. The radiation anneal can be either by scanning using a laser beam or a flash tool that provides the anneal to the whole dielectric layer simultaneously. The heat is intense, preferably 900-1400 degrees Celcius, but for a very short duration of less than 10 milliseconds; preferably about 1 millisecond or even shorter. The result of the radiation anneal can also be used to activate the source/drain. Thus, this type of radiation anneal can result in a larger change in stress, activation of the source/drain, and still no expansion of the source/drain.

### FIELD OF THE INVENTION

This invention relates to semiconductor devices, and more particularly, to a method for straining a semiconductor device.

### RELATED ART

In the manufacture of semiconductor devices, silicon has been by far the most popular choice for the semiconductor material. Transistor performance has been enhanced regularly through a variety of process improvements. One of the improvements has been to alter the strain in the device in order to improve mobility. Some of the techniques have included using other materials in addition to the silicon to bring about the strain and the consequent mobility improvement. For example, a silicon layer that has germanium added results in a silicon germanium layer that is under compressive stress. Such a silicon germanium layer under compressive stress is useful in improving the mobility of the carriers for a P-channel transistor.

Creating tensile stress on an NMOS (N-type metal oxide semiconductor) device is useful for improving carrier mobility for an N-channel transistor.

A variety of techniques have been developed for achieving both tensile and compressive stresses. The carrier mobility improves with increases in stress, but too much stress can cause fractures or extended defects in one or more layers of the device.

Thus, there is a need to provide for carrier mobility enhancement without damaging the device.

### BRIEF DESCRIPTION OF THE DRAWINGS

The foregoing and further and more specific objects and advantages of the instant invention will become readily apparent to those skilled in the art from the following detailed description of a preferred embodiment thereof taken in conjunction with the following drawings:

FIG. 1 illustrates a cross-sectional view of a portion of a partially completed semiconductor device in accordance with one embodiment.

FIG. 2 illustrates the semiconductor device of FIG. 1 after the formation of a pre-metal dielectric layer.

FIG. 3 illustrates the semiconductor device of FIG. 2 during an anneal process.

FIG. 4 illustrates the semiconductor device of FIG. 3 after the anneal process is complete.

### DETAILED DESCRIPTION OF THE PREFERRED EMBODIMENT

Generally, the present invention provides a method for making a semiconductor device. The method includes forming a dielectric layer over a semiconductor layer. A radiation is applied to the dielectric layer for a duration not exceeding 10 milliseconds to cause a change in the stress of the dielectric layer. The application of the radiation may also activate source and drain regions of a transistor formed in the device. Applying the radiation for a short duration not exceeding 10 milliseconds provides the needed performance gains without adding significantly to the thermal budget for making the device. In addition, the stress is added using the same process step used to activate the source and drain. In one embodiment the radiation is applied using a laser.

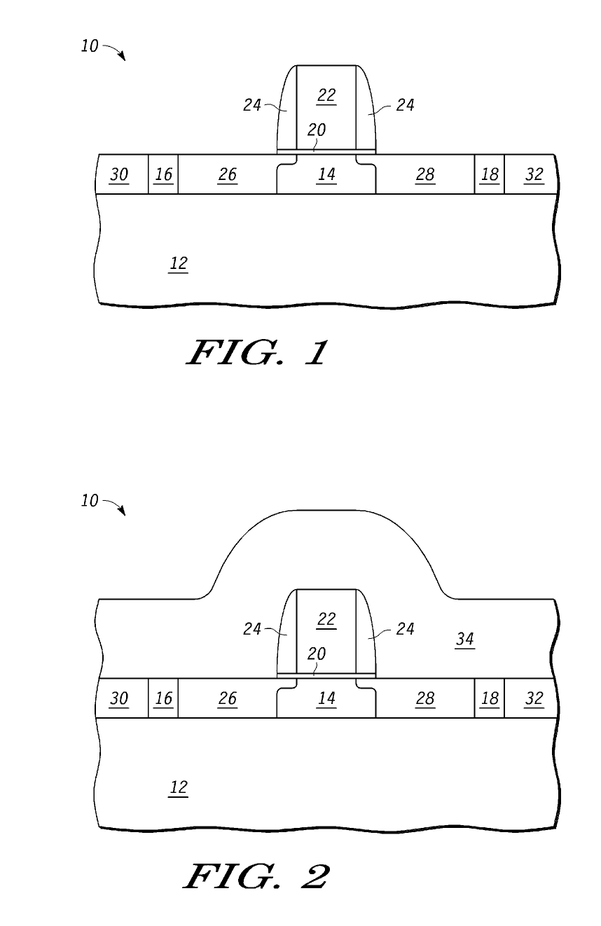

FIG. 1 illustrates a cross-sectional view of a portion of a partially completed semiconductor device 10 in accordance with one embodiment. In one embodiment, semiconductor device 10 includes an N-channel transistor formed on an SOI (silicon-on-insulator) substrate 12. In another embodiment, substrate 12 may be bulk silicon. Generally the N-channel transistor is a conventional N-channel transistor and is representative of many N-channel transistors formed on device 10. Device 10 may also include P-channel transistors (not shown). Device 10 includes a semiconductor layer 14. Semiconductor layer 14 may be isolated using trench isolation such as for example shallow trench isolation (STI) structures 16 and 18. Source region 26 and drain region 28 are formed in the semiconductor layer 14 and are doped using p-type dopants. A gate dielectric layer is formed over the semiconductor layer 14 and a gate electrode layer is formed over the dielectric layer. Both the gate dielectric layer 20 and the gate electrode layer 22 are patterned as illustrated in FIG. 1 to form a patterned gate dielectric 22 and gate electrode 22 between the source region 26 and the drain region 28. The gate dielectric layer 20 may be formed using any suitable insulating material, such as for example, an oxide or a high-k dielectric. The gate electrode layer 22 may be formed using any suitable conductive material, such as for example, a metal, a conductive metal oxide, or polysilicon. Side wall spacers 24 are formed on the sides of the gate electrode and generally comprise nitride. Source and drain regions 30 and 32 are for other transistors not illustrated in FIG. 1. The other transistors may be, for example, P-channel transistors.

FIG. 2 illustrates semiconductor device 10 of FIG. 1 after the formation of a pre-metal dielectric layer 34. The pre-metal dielectric layer 34 is a plasma enhanced chemical vapor deposition (PECVD) dielectric layer comprising Si_{X}N_{Y}H_{Z} using a combination of growth chemicals or precursors comprising one or more of SiH₄, NH₃, N₂, TMS (TriMethylSilane), He, Ar, or H₂. Preferably, dielectric layer 34 comprises at least 30 atomic percent Hydrogen. The pre-metal layer is typically deposited at between 300-550 degrees Celsius at a sub-atmospheric pressure. The pre-metal layer is deposited to a thickness that will result in a thickness of about 300-1200 angstroms after radiation anneal (described below).

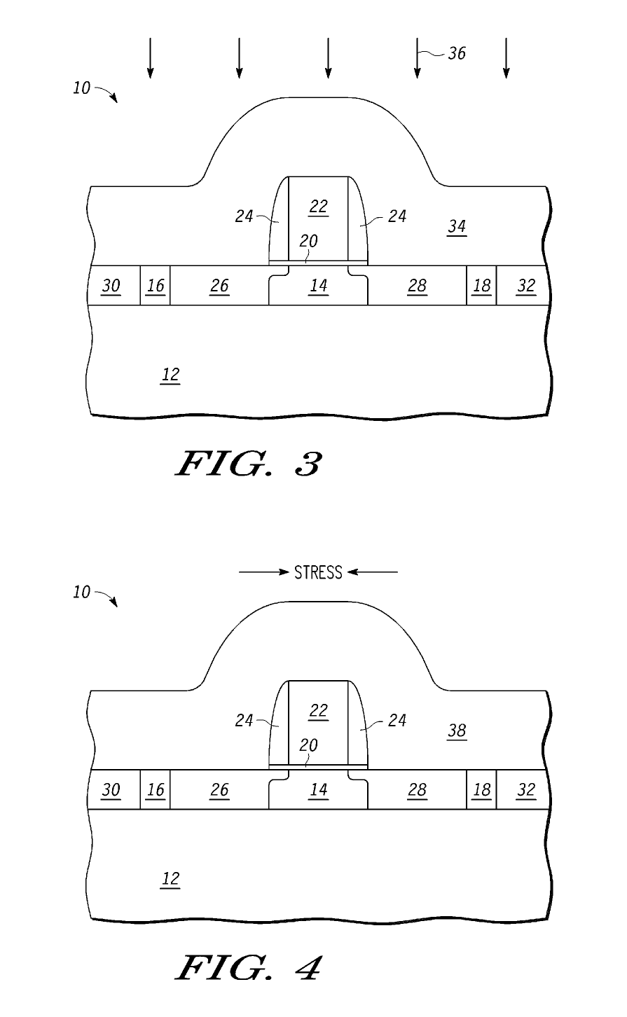

FIG. 3 illustrates semiconductor device 10 during a radiation anneal process. After deposition of the pre-metal dielectric layer 34, the semiconductor device 10 is radiated with a radiation 36 using a laser tool. A wafer having the device 10 is placed in the tool on a chuck that is pre-heated to between about 350-500 degrees Celsius, and preferably 400-425 degrees Celsius. The tool then causes the wafer to be scanned and locally exposes substantially the entire surface of the device using a predetermined scan pattern. In a preferred embodiment, the surface is exposed for about 1 millisecond to locally heat the device to about 900 to 1400 degrees Celsius. In other embodiments, the length of time device 10 is radiated is dependent on, for example, the power of the laser, the laser beam width, and the desired temperature. Also, the device 10 is radiated in an ambient atmosphere, or a controlled atmosphere containing one or more of air, Ar, He, N₂, or the like. In addition, the device can be radiated with an absorber layer (not shown). The absorber layer can be used to reduce pattern density and material absorption effects in the device. The laser tool used in the radiation anneal process is an Ultratech LSA-100 available through Ultratech, Inc. In another embodiment, device 10 may be heated using a commonly available flash lamp tool that subjects the device to sufficient heat in a relatively short period of time. Heating the surface of device 10 causes pre-metal dielectric layer 34 to shrink and apply stress to substrate 12 as illustrated in FIG. 4. In addition, the application of radiation 36 activates source and drain regions 26 and 28, respectively. Note that the source and drain regions 30 and 32 of P-channel devices (not shown) are also activated at the same time. Because of the relatively short duration of radiation 36, diffusion of the dopants used to create source region 26 and drain region 28 is limited to less than about 20 angstroms.

FIG. 4 illustrates the semiconductor device of FIG. 3 after the radiation anneal process is complete to produce an annealed pre-metal dielectric layer 38 having tensile stress. Annealed pre-metal dielectric layer 38 produces a strain in the substrate 12. The strain increases carrier mobility, thus allowing an increased drain-to-source current in the N-channel transistor of device 10 over an unstrained device.

Because the annealed pre-metal dielectric layer 38 has tensile stress, it may not enhance carrier mobility for P-channel transistors, therefore in some embodiments the pre-metal dielectric layer 38 may be removed from over the P-channel devices (not shown).

Also, heating the substrate 12 for a relatively short period of time reduces a likelihood of cracks or fractures from forming in the annealed pre-metal dielectric layer 38. In addition, the strain is applied using the same process step that activates the dopants in the source and drain regions. Further, applying the radiation for a short duration not exceeding 10 milliseconds provides the mobility performance gain without adding significantly to the thermal budget for making the device.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of the present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. The terms a or an, as used herein, are defined as one or more than one. The terms including and/or having, as used herein, are defined as comprising (i.e., open language). As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A method, comprising:
providing a substrate having a semiconductor layer;
forming a first dielectric layer having a stress over the semiconductor layer;
applying a radiation anneal over the first dielectric layer of a duration not exceeding 10 milliseconds to cause a change in the stress of the dielectric layer.

2. The method of claim 1, further comprising:
forming a gate over the semiconductor layer; and
forming a first source/drain and a second source/drain in the semiconductor layer aligned to sides of the gate; wherein
the step of forming the first dielectric layer is performed after the steps of forming the gate and forming the first and second source/drains.

3. The method of claim 2, wherein the step of applying the radiation anneal causes activation of the first and second source/drains.

4. The method of claim 2, wherein the step of forming the first dielectric layer is further characterized by the first dielectric layer being nitride.

5. The method of claim 4, wherein the step of forming the first dielectric layer is further characterized by the first dielectric layer being deposited by plasma-enhanced chemical vapor deposition (PECVD).

6. The method of claim 2, wherein:
the step of forming the first and second source/drains is further characterized by the first and second source/drain regions each have a boundary; and
the step of applying the radiation anneal is further characterized by moving the boundaries of the first and second source/drains by a distance in the range of 0-20 Angstroms.

7. The method of claim 1, wherein the step of applying the radiation anneal is performed by a tool comprising one of a group consisting of a laser tool and a flash tool.

8. The method of claim 7, wherein the step of applying the radiation anneal is further characterized as scanning over the first dielectric layer with a laser beam.

9. The method of claim 8, wherein the step of applying the radiation anneal is further characterized by the scanning comprising moving the substrate while keeping the laser beam stationary.

10. The method of claim 8, wherein the step of applying the radiation anneal is further characterized by the scanning comprising moving the laser beam while keeping the substrate stationary.

11. The method of claim 8, wherein the step of applying the radiation anneal is further characterized by the scanning resulting in about a one millisecond anneal.

12. The method of claim 7, wherein the step of applying the radiation anneal is further characterized as being a flash of radiation using the flash tool, wherein the flash of radiation is simultaneously over all of the first dielectric layer.

13. The method of claim 7, wherein the forming the first dielectric layer comprises:
forming a nitride layer by PECVD using silane, ammonia, nitrogen, and hydrogen to result in the nitride layer having a hydrogen concentration of at least 30 atomic percent.

14. The method of claim 7, wherein the step of applying the radiation anneal is further characterized as changing the stress in the first dielectric layer by at least one gigapascal and causing a strain in the semiconductor layer.

15. The method of claim 7, wherein the step of applying the radiation anneal is further characterized as causing a temperature of 900 to 1400 degrees Celcius in the first dielectric layer.

16. The method of claim 1, wherein the step of applying the radiation anneal is further characterized as applying the radiation anneal directly on the first dielectric layer.

17. A method, comprising:
providing a semiconductor substrate;
forming a dielectric layer over the substrate, wherein the dielectric layer has a characteristic stress when formed; and
applying radiation over the semiconductor substrate to change the dielectric layer from the characteristic stress to a changed stress.

18. The method of claim 17, wherein the step of applying the radiation is further characterized by a difference between the characteristic stress and the changed stress being at least one gigapascal that causes a strain in a surface region of the semiconductor substrate.

19. The method of claim 18, wherein the forming the dielectric layer comprises forming a nitride layer by PECVD using silane, ammonia, nitrogen, and hydrogen to result in the nitride layer having a hydrogen concentration of at least 30 atomic percent.

20. The method of claim 17 further comprising forming a source/drain in the semiconductor substrate prior to forming the dielectric layer, wherein the source/drain has a boundary.

21. The method of claim 18, wherein the step of applying the radiation activates the source/drain while not changing the boundary of the source/drain by more than 20 Angstroms.

22. A method, comprising:
providing a semiconductor substrate;
forming a source/drain in the semiconductor substrate, wherein the source/drain has a boundary;
forming a dielectric layer over the substrate after forming the source/drain, wherein the dielectric layer has a stress; and
applying radiation over the semiconductor substrate to change the stress in the dielectric layer while not moving the boundary more than 20 Angstroms.

23. The method of claim 22, wherein the step of applying the radiation is further characterized by
the radiation causing a temperature in the range of 900 to 1400 degrees Celsius in the dielectric layer;
the radiation activating the source/drain.

24. The method of claim 23, wherein the step of applying the radiation is performed by a tool comprising one of a group consisting of a laser tool and a flash tool, wherein the laser tool applies the radiation as a laser beam by scanning and the flash tool applies the radiation in a flash of all of the dielectric layer.

25. The method of claim 24, wherein the step of applying the radiation causes a change in strain in a surface area of the semiconductor substrate.
